(19) United States
(12) Patent Application Publication
(10) Pub. No.: US 2026/0143583 A1
(43) Pub. Date: May 21, 2026

(54) COMPOSITE CIRCUIT BOARD STRUCTURE

(71) Applicant: MLMTEK Co., Ltd., Taoyuan City (TW)

(72) Inventor: YU-CHIA CHANG, New Taipei City (TW)

(21) Appl. No.: 19/375,226

(22) Filed: Oct. 31, 2025

(30) Foreign Application Priority Data
Nov. 20, 2024 (TW) 113144679

(51) Int. Cl. H05K 1/02; H05K 1/03

(52) U.S. Cl. CPC H05K 1/0206; H05K 1/0306; H05K 2201/064

(57) ABSTRACT

A composite circuit board structure has a component bonding area and a circuit layout area. The composite circuit board structure includes a glass substrate, a conductive circuit, a bottom substrate, a liquid-cooled heat-conducting channel structure, and a heat conduction structure. The conductive circuit is arranged on the upper surface of the glass substrate and distributed within the component bonding area and the circuit layout area. The bottom substrate is arranged on the lower surface of the glass substrate. The liquid-cooled heat-conducting channel structure is arranged in the glass substrate or the bottom substrate. One end of the liquid-cooled heat-conducting channel structure is connected to the coolant inlet, and another end of the liquid-cooled heat-conducting channel structure is connected to the coolant outlet, for allowing circulation of a cooling liquid therethrough. The heat conduction structures are arranged in the glass substrate and separated from the liquid-cooled heat-conducting channel structure.

### CROSS-REFERENCE TO RELATED PATENT APPLICATION

This application claims the benefit of priority to Taiwan Patent Application No. 113144679, filed on Nov. 20, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board structure, and more particularly to a composite circuit board structure with a glass substrate.

### BACKGROUND OF THE DISCLOSURE

In the modern semiconductor industry, the printed circuit board (PCB) serves as a substrate for carrying various electronic components and conductive circuits, and is widely used in consumer electronics, medical devices, industrial equipment, lighting, automobiles, and the aerospace industry. Currently, the most commonly used materials for the PCB are fiberglass and resin. The glass material is widely used in electronic devices such as display panels due to its high flatness and excellent heat dissipation capability.

However, the heat generated by various electronic components during operation will increase with increasing computing power. The high temperatures generated by the electronic components can degrade their operational efficiency and performance over time, eventually causing the components to malfunction.

### SUMMARY OF THE DISCLOSURE

In response to the above-referenced technical inadequacy, the present disclosure provides a composite circuit board structure, which can simultaneously have a liquid-cooled heat-conducting channel structure and multiple heat conduction structures.

In order to solve the above-mentioned problems, one of the technical aspects adopted by the present disclosure is to provide a composite circuit board structure having a component bonding area and a circuit layout area, which includes a glass substrate, at least one conductive circuit, a bottom substrate, a liquid-cooled heat-conducting channel structure and a plurality of heat conduction structures. The glass substrate has an upper surface and a lower surface. The at least one conductive circuit is disposed on the upper surface of the glass substrate and continuously distributed within the component bonding area and the circuit layout area. The bottom substrate is disposed on the lower surface of the glass substrate to contact the lower surface of the glass substrate. The liquid-cooled heat-conducting channel structure is disposed inside the glass substrate or the bottom substrate, and the liquid-cooled heat-conducting channel structure is disposed within the circuit layout area and the component bonding area. The heat conduction structures are disposed inside the glass substrate located within the component bonding area. The heat conduction structures extend from the upper surface of the glass substrate to the lower surface of the glass substrate, and each of the heat conduction structures is adjacent to and separated from the liquid-cooled heat-conducting channel structure. The liquid-cooled heat-conducting channel structure is configured to allow a coolant to flow therein (or allow a cooling liquid to circulate through it).

In order to solve the above-mentioned problems, another one of the technical aspects adopted by the present disclosure is to provide a composite circuit board structure, which includes a glass substrate, at least one conductive circuit, a bottom substrate, a liquid-cooled heat-conducting channel structure and a plurality of heat conduction structures. The glass substrate has an upper surface and a lower surface. The at least one conductive circuit is disposed on the upper surface of the glass substrate. The bottom substrate is disposed on the lower surface of the glass substrate to contact the lower surface of the glass substrate. The liquid-cooled heat-conducting channel structure passes through the glass substrate to contact an upper surface of the bottom substrate. The heat conduction structures are disposed on the glass substrate and separated from the liquid-cooled heat-conducting channel structure. The liquid-cooled heat-conducting channel structure and the heat conduction structures are disposed inside the same glass substrate and arranged side by side horizontally or vertically. The liquid-cooled heat-conducting channel structure and the heat conduction structures are not disposed inside the bottom substrate.

In order to solve the above-mentioned problems, yet another one of the technical aspects adopted by the present disclosure is to provide a composite circuit board structure, which includes a glass substrate, at least one conductive circuit, a bottom substrate, a liquid-cooled heat-conducting channel structure and a plurality of heat conduction structures. The glass substrate has an upper surface and a lower surface. The at least one conductive circuit is disposed on the upper surface of the glass substrate. The bottom substrate is disposed on the lower surface of the glass substrate to contact the lower surface of the glass substrate. The liquid-cooled heat-conducting channel structure passes through the bottom substrate to contact the lower surface of the glass substrate. The heat conduction structures are disposed inside both the glass substrate and the bottom substrate and separated from the liquid-cooled heat-conducting channel structure. The liquid-cooled heat-conducting channel structure and the heat conduction structures are arranged side by side in a horizontal direction. The liquid-cooled heat-conducting channel structure is not disposed inside the glass substrate.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a composite circuit board structure according to one embodiment of the present disclosure;

FIG. 2 is a schematic cross-sectional view of the composite circuit board structure according to one embodiment of the present disclosure (or a schematic cross-sectional view taken along line II-II of FIG. 1);

FIG. 3 is a schematic cross-sectional view of the composite circuit board structure according to another embodiment of the present disclosure; and

FIG. 4 is a schematic cross-sectional view of the composite circuit board structure according to yet another embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiments

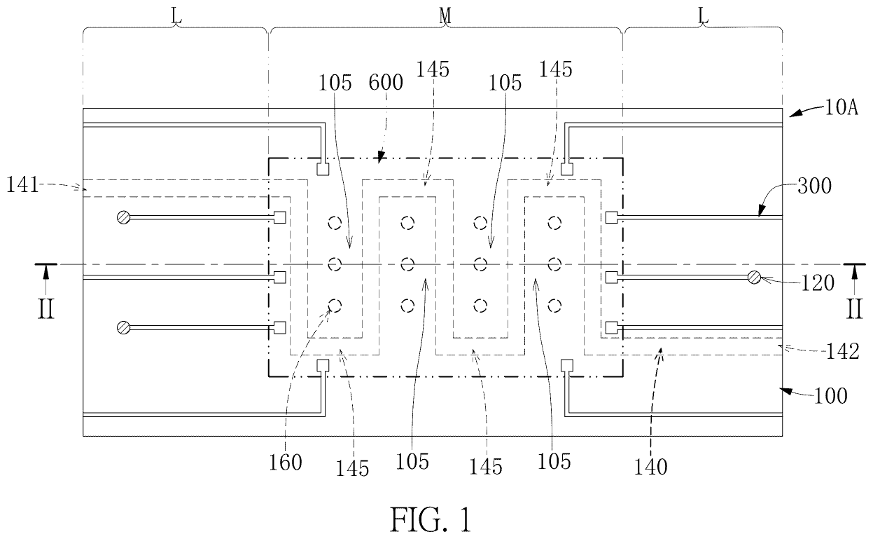

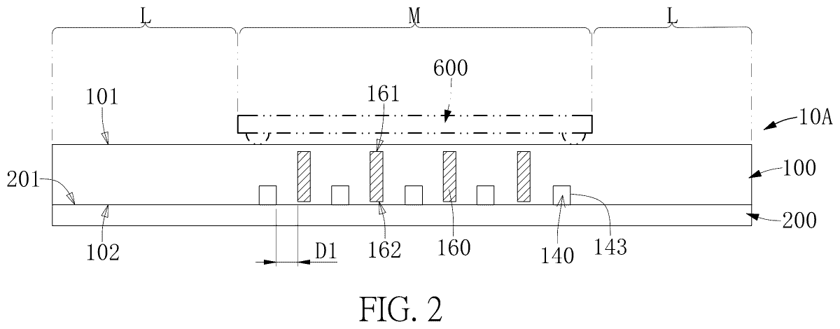

Firstly, FIG. 1 is a schematic top view of a composite circuit board structure according to one embodiment of the present disclosure, and FIG. 2 is a schematic cross-sectional view of the composite circuit board structure according to one embodiment of the present disclosure. Referring to FIG. 1 and FIG. 2, one embodiment of the present disclosure provides a composite circuit board structure 10A (or a circuit board structure, or a composite substrate structure) which may include at least one component bonding area M (or a chip-carrying region) and at least one circuit layout area L (FIG. 1 and FIG. 2 take two circuit layout areas L or two circuit areas as examples for explanation), and the composite circuit board structure 10A may also include at least one the glass substrate 100 (such as not being an FR4 fiberglass substrate) and at least one bottom substrate 200 (or a baseboard). For example, in one feasible embodiment of the present disclosure, the thickness of the glass substrate 100 may be between 50 μm and 500 μm (such as any positive integer between 50 μm and 500 μm), and the glass substrate 100 can be configured as an aluminosilicate glass, an aluminoborosilicate glass, a barium borosilicate glass, or any type of glass. Moreover, when the subsequent processing temperature is high, it is best to use a glass substrate with a strain point above 730° C. (or above a predetermined temperature). In addition, the circuit board made of the glass substrate 100 can be used in a light-transmitting device. Compared to the printed circuit board made of fiberglass and resin materials, the glass substrate has better thermal conductivity. Therefore, for electronic components (or electronic chips) that easily generate heat during operation, the glass substrate can provide better heat dissipation. However, the aforementioned details are disclosed for exemplary purposes only, and are not meant to limit the scope of the present disclosure.

More particularly, referring to FIG. 1 and FIG. 2, a plurality of conductive traces 300 (or at least one conductive trace) can be disposed on the upper surface 101 (or top surface) of the glass substrate 100, and the conductive traces 300 can be continuously distributed within the component bonding area M and the circuit layout area L, so that the electronic signal can be transmitted from one area to another area. For example, in one feasible embodiment of the present disclosure, at least one electronic component 600 (or multiple electronic components) disposed within the component bonding area M can transmit signals to another electronic component (not shown) disposed on another area through a plurality of conductive circuits 300 that are disposed on the circuit layout area L. In addition, the conductive circuits 300 can be configured as a metal layer (such as a copper foil layer) formed on the glass substrate 100 by etching, or the conductive circuit 300 can be configured as a circuit structure layer formed with a specific circuit design layout pattern. However, the aforementioned details are disclosed for exemplary purposes only, and are not meant to limit the scope of the present disclosure.

For example, referring to FIG. 1 and FIG. 2, in one feasible embodiment of the present disclosure, the composite circuit board structure 10A may include at least one conductive penetration structure 120 (or multiple conductive penetration structures, or multiple conductive vias) according to different functional requirements, and the at least one conductive penetration structure 120 may be disposed on the glass substrate 100 located within the circuit layout area L (or the at least one conductive penetration structure 120 can pass through the glass substrate 100) and electrically connected to the conductive trace 300. Moreover, the conductive traces 300 located on the upper surface 101 of the glass substrate 100 can be electrically connected to the lower surface 102 (or bottom surface) of the glass substrate 100 through the at least one conductive penetration structure 120 (or multiple conductive penetration structures 120), thereby further electrically connecting to a conductive trace (not shown in figures) disposed on the lower surface 102 of the glass substrate 100. In addition, the conductive penetration structure 120 can be formed, for example, by mechanical drilling or laser processing. It should be noted that in one feasible embodiment of the present disclosure, after a through hole is pre-formed on the glass substrate 100, the through hole (or the inner wall of the through hole) can be filled (or covered) with a highly conductive material (such as copper or silver), thereby forming a conductive penetration structure 120 that can be configured as a via hole (such as a blind hole or a buried hole). However, the aforementioned details are disclosed for exemplary purposes only, and are not meant to limit the scope of the present disclosure.

More particularly, referring to FIG. 1 and FIG. 2, a liquid-cooled heat-conducting channel structure 140 (or heat conduction channel, or heat dissipation channel) can be disposed on the lower surface 102 of the glass substrate 100 (or the liquid-cooled heat-conducting channel structure 140 can pass through the glass substrate 100 and contact at least one bottom substrate 200), and the liquid-cooled heat-conducting channel structure 140 can be distributed on the circuit layout area L and the component bonding area M of the composite circuit board structure 10A. For example, in one feasible embodiment of the present disclosure, one end (or a first side) of the liquid-cooled heat-conducting channel structure 140 can be communicated with a coolant inlet 141 (or cooling liquid inlet), and another end (or a second side) of the liquid-cooled heat-conducting channel structure 140 can be communicated with a coolant outlet 142 (or cooling liquid outlet). Moreover, the liquid-cooled heat-conducting channel structure 140 can be formed (such as by laser processing) to form a shallow groove 143 on the lower surface 102 of the glass substrate 100 (for example, a continuous recessed area can be formed inwardly from the lower surface 102 of the glass substrate 100). In addition, after forming the shallow grooves 143 of the liquid-cooled heat-conducting channel structure 140, the bottom substrate 200 can be disposed (such as fixed, bonded or adhered) on (to) the lower surface 102 of the glass substrate 100, so that the upper surface 201 of the bottom substrate 200 can seal (or hermetically seal, or tightly cover) the shallow grooves 143 of the liquid-cooled heat-conducting channel structure 140, thereby forming a liquid-cooled heat-conducting channel structure 140 (or a sealed heat conduction via structure with two terminal openings) at the interface (the connection position) between the glass substrate 100 and the bottom substrate 200. However, the above example is only one feasible embodiment and is not intended to limit the present disclosure.

For example, referring to FIG. 1 and FIG. 2, in one feasible embodiment of the present disclosure, the positions of the coolant inlet 141 and the coolant outlet 142 can be changed according to different requirements. More particularly, the coolant inlet 141 and the coolant outlet 142 can be located on the same side of the glass substrate 100, or on different sides (such as two opposite sides or two adjacent sides) of the glass substrate 100. In addition, the coolant inlet 141 and the coolant outlet 142 can be connected to an external coolant circulation device (not shown), and the power provided by the external coolant circulation device can be used to circulate the coolant within the liquid-cooled heat-conducting channel structure 140, so that the coolant can flow from the coolant inlet 141 to the coolant outlet 142 through the liquid-cooled heat-conducting channel structure 140. However, the aforementioned details are disclosed for exemplary purposes only, and are not meant to limit the scope of the present disclosure.

For example, referring to FIG. 1 and FIG. 2, in one feasible embodiment of the present disclosure, the liquid-cooled heat-conducting channel structure 140 located within the component bonding area M may include a plurality of curved portions 145 connected with each other (or multiple meandering portions connected in sequence) to increase the path length (extension length) of the liquid-cooled heat-conducting channel structure 140 within the component bonding area M. In addition, the profile (such as an arcuate profile) of the curved portion 145 can be changed according to different requirements to reduce the processing complexity of the glass substrate 100 and reduce the processing stress on the glass substrate 100. However, the aforementioned details are disclosed for exemplary purposes only, and are not meant to limit the scope of the present disclosure.

For example, referring to FIG. 1 and FIG. 2, in one feasible embodiment of the present disclosure, the area contained in the lower surface 102 of the glass substrate 100 can be divided into a plurality of regions by the liquid-cooled heat-conducting channel structure 140, so that the glass substrate 100 can be divided into a plurality of finger-shaped protrusions 105 that can be separated from each other and arranged alternately as viewed from a top view of FIG. 1. However, the aforementioned details are disclosed for exemplary purposes only, and are not meant to limit the scope of the present disclosure.

More particularly, referring to FIG. 1 and FIG. 2, multiple heat conduction structures 160 (heat conduction via structures, or thermal vias, or physical thermally conductive pillars) can be disposed on the glass substrate 100 located within the component bonding area M. Each heat conduction structure 160 can extend from the upper surface 101 of the glass substrate 100 to the lower surface 102 of the glass substrate 100. Each heat conduction structure 160 is adjacent to and separated from the liquid-cooled heat-conducting channel structure 140 by a predetermined distance. It should be noted that the heat conduction structures 160 and the liquid-cooled heat-conducting channel structure 140 can be disposed simultaneously on the same glass substrate 100. In addition, the heat conduction structures 160 (or heat-conducting through-hole structure) can be arranged horizontally or side-by-side with the liquid-cooled heat-conducting channel structure 140, so that the heat absorbed by each heat conduction structure 160 can be conducted or transferred to the liquid-cooled heat-conducting channel structure 140 along in a horizontal direction (or not in a vertical direction). For example, in one feasible embodiment of the present disclosure, the heat conduction structure 160 can be formed by etching (or drilling) the glass substrate 100 (such as using laser processing) to form multiple thermal channels in advance. After etching (or drilling) the glass substrate 100 to form the multiple thermal channels, each thermal channel may be filled with a material having good thermal conductivity (such as the same filling material as the conductive penetration structures 120), thereby completing the formation of the heat conduction structures 160. However, the aforementioned details are disclosed for exemplary purposes only, and are not meant to limit the scope of the present disclosure.

For example, referring to FIG. 1 and FIG. 2, in one feasible embodiment of the present disclosure, the heat conduction structures 160 may be disposed within the finger-shaped protrusions 105 of the glass substrate 100, so that at least two opposite sides of each heat conduction structure 160 can face the liquid-cooled heat-conducting channel structure 140. Furthermore, the top side 161 of each heat conduction structure 160 can be adjacent to the upper surface 101 of the glass substrate 100 (but does not pass through the upper surface 101 of the glass substrate 100), and the bottom side 162 of each heat conduction structure 160 can be adjacent to the lower surface 102 of the glass substrate 100 (but does not pass through the lower surface 102 of the glass substrate 100), so that each heat conduction structure 160 cannot be exposed from the glass substrate 100 and can be insulated from the conductive circuit 300. Moreover, the heat conduction function provided by the heat conduction structure 160 is different from the electrical conduction function provided by the conductive penetration structure 120. The heat conduction structure 160 can only be used to transfer heat and accelerate heat dissipation, so that the heat conduction structure 160 is not used to electrically connect to the conductive circuit 300 or the electronic component 600. In addition, the distance D1 (horizontal distance or shortest distance) between the bottom side 162 of the heat conduction structure 160 and the liquid-cooled heat-conducting channel structure 140 can be changed according to the material of the glass substrate 100 (for example, in one embodiment, the distance D1 between the bottom side 162 of the heat conduction structure 160 and the liquid-cooled heat-conducting channel structure 140 can be less than 5 μm, or any positive integer less than 5000 nm). It should be noted that the bottom side 162 of the heat conduction structure 160 can be adjacent to the liquid-cooled heat-conducting channel structure 140 but not directly connected to the liquid-cooled heat-conducting channel structure 140, so that the present disclosure can avoid the leakage of the coolant from the liquid-cooled heat-conducting channel structure 140 without affecting the heat conduction efficiency. Moreover, the present disclosure can provide a liquid-cooled heat-conducting channel structure 140 having a plurality of curved portions 145 within the component bonding area M, so that the heat exchange area of the liquid-cooled heat-conducting channel structure 140 within the component bonding area M can be increased, thereby enabling the coolant in the liquid-cooled heat-conducting channel structure 140 to better absorb the heat directly transferred from the electronic component 600 located within the component bonding area M through the glass substrate 100. In addition, each finger-shaped protrusion 105 of the glass substrate 100 can provide a plurality of heat conduction structures 160, so that at least two opposite sides of the heat conduction structures 160 can face the liquid-cooled heat-conducting channel structure 140, thereby further accelerating the speed of transferring the heat generated by the electronic component 600 to the liquid-cooled heat-conducting channel structure 140 without increasing the number of the heat conduction structures 160. However, the aforementioned details are disclosed for exemplary purposes only, and are not meant to limit the scope of the present disclosure.

It should be noted that, for example, in one feasible embodiment of the present disclosure, the material of the bottom substrate 200 provided by the present disclosure can be selected according to different requirements (for example, the bottom substrate 200 can be made of the same material as or different from the glass substrate 100, or the bottom substrate 200 can be made of a waterproof material). In addition, the bottom substrate 200 can be fixed on or connected to the glass substrate 100 by anodic bonding or sintering bonding. However, the aforementioned details are disclosed for exemplary purposes only, and are not meant to limit the scope of the present disclosure.

It should be noted that, for example, in one feasible embodiment of the present disclosure, the composite circuit board structure 10A may include a plurality of component bonding areas M, and the required passive components (such as resistors, capacitors or inductors) or electronic components (such as chip packaging structures containing chips) can be set within the scope of each component bonding area M. However, the aforementioned details are disclosed for exemplary purposes only, and are not meant to limit the scope of the present disclosure.

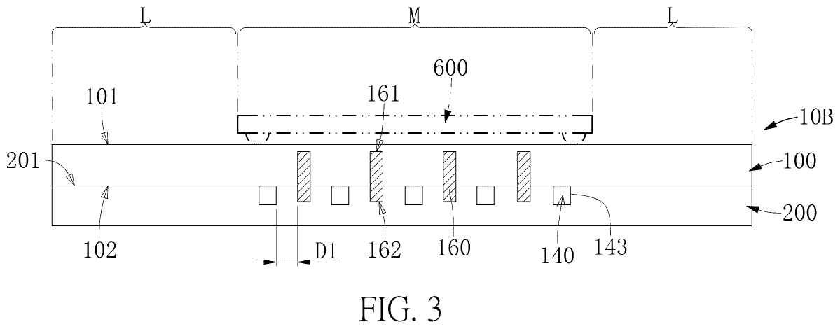

More particularly, FIG. 3 is a schematic cross-sectional view of the composite circuit board structure according to another embodiment of the present disclosure. The embodiment shown in FIG. 3 is similar to the embodiment shown in FIG. 2. The main difference between the two embodiments is as follows: in the composite circuit board structure 10B, the liquid-cooled heat-conducting channel structure 140 can be disposed on the upper surface 201 of the bottom substrate 200 rather than on the lower surface 102 of the glass substrate 100. For example, the liquid-cooled heat-conducting channel structure 140 can be formed (such as by laser processing) to form a shallow groove 143 on the upper surface 201 of the bottom substrate 200 (for example, a continuous recessed area can be formed inwardly from the upper surface 201 of the bottom substrate 200). In addition, after forming the shallow grooves 143 of the liquid-cooled heat-conducting channel structure 140, the bottom substrate 200 can be disposed (such as fixed, bonded or adhered) on (to) the lower surface 102 of the glass substrate 100, so that the lower surface 102 of the glass substrate 100 can seal (or hermetically seal, or tightly cover) the shallow grooves 143 of the liquid-cooled heat-conducting channel structure 140, thereby forming a liquid-cooled heat-conducting channel structure 140 (or a sealed heat conduction via structure with two terminal openings) at the interface (the connection position) between the glass substrate 100 and the bottom substrate 200. It should be noted that the liquid-cooled heat-conducting channel structure 140 can be disposed on the upper surface 201 of the bottom substrate 200, so that the number of processing steps for the glass substrate 100 can be reduced, thereby reducing the impact of internal stress accumulation on the glass substrate 100 during processing. In addition, when the bottom substrate 200 is made of a material (such as a non-glass material) that is easy to process, the processing difficulty of the liquid-cooled heat-conducting channel structure 140 can also be reduced. However, the aforementioned details are disclosed for exemplary purposes only, and are not meant to limit the scope of the present disclosure.

More particularly, as shown in FIG. 3, the bottom side 162 of the heat conduction structure 160 can further extend into the bottom substrate 200, and the bottom side 162 (or bottom portion) of each heat conduction structure 160 can be separated from the liquid-cooled heat-conducting channel structure 140 by a predetermined distance in the horizontal direction or along the horizontal direction. For example, in one feasible embodiment of the present disclosure, the distance D2 (or the horizontal distance, or the shortest distance) between the heat conduction structure 160 and the liquid-cooled heat-conducting channel structure 140 can be less than 5 μm (or any positive integer less than 5000 nm). In addition, the height (distance) of the bottom side 162 of the heat conduction structure 160 relative to the lower surface of the bottom substrate 200 can be the same as or similar to the height (distance) of the bottom side of the liquid-cooled heat-conducting channel structure 140 relative to the lower surface of the bottom substrate 200. Alternatively, the height (distance) of the bottom side 162 of the heat conduction structure 160 relative to the lower surface of the bottom substrate 200 can be lower (or smaller) than the height (distance) of the bottom side of the liquid-cooled heat-conducting channel structure 140 relative to the lower surface of the bottom substrate 200, thereby increasing the efficiency of transferring heat from the heat conduction structure 160 to the liquid-cooled heat-conducting channel structure 140. It should be noted that a portion of each heat conduction structure 160 and the liquid-cooled heat-conducting channel structure 140 can be simultaneously disposed inside the same bottom substrate 200, and the heat-conducting through-hole structures 160 can be arranged side by side with the liquid-cooled heat-conducting channel structure 140 in the horizontal direction or along the horizontal direction. However, the aforementioned details are disclosed for exemplary purposes only, and are not meant to limit the scope of the present disclosure.

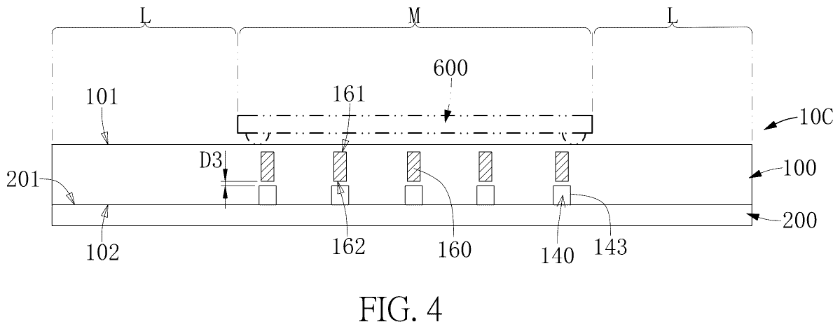

More particularly, FIG. 4 is a schematic cross-sectional view of the composite circuit board structure according to yet another embodiment of the present disclosure. The embodiment shown in FIG. 4 is similar to the embodiment shown in FIG. 2. The main difference between the two embodiments is as follows: in the composite circuit board structure 10C, the heat conduction structure 160 can be disposed inside the glass substrate 100 and directly above the liquid-cooled heat-conducting channel structure 140 (that is to say, the vertical projection of the heat conduction structure 160 can fall entirely or partially on the liquid-cooled heat-conducting channel structure 140). In addition, the top side 161 of the heat conduction structure 160 can be adjacent to the upper surface 101 of the glass substrate 100 (but not exposed from the upper surface 101 of the glass substrate 100), and the bottom side 162 of the heat conduction structure 160 can be adjacent to the liquid-cooled heat-conducting channel structure 140 (but not arranged side by side with the liquid-cooled heat-conducting channel structure 140 in the horizontal direction or along the horizontal direction). That is to say, the heat conduction structures 160 and the liquid-cooled heat-conducting channel structure 140 can be simultaneously disposed inside the same glass substrate 100, and the heat conduction structures 160 can be arranged side by side with the liquid-cooled heat-conducting channel structure 140 in a vertical direction (or along a vertical direction), so that the heat absorbed by each heat conduction structure 160 can be conducted or transferred to the liquid-cooled heat-conducting channel structure 140 in a vertical direction (such as not in a horizontal direction). For example, in one feasible embodiment of the present disclosure, the distance D3 (or the vertical distance or the shortest distance) between the bottom side 162 of the heat conduction structure 160 and the liquid-cooled heat-conducting channel structure 140 can be less than 5 μm (or any positive integer less than 5000 nm). In addition, the heat conduction structures 160 can be positioned directly above the liquid-cooled heat-conducting channel structure 140, so that the heat generated by the electronic component 600 can be directly transferred downward to the liquid-cooled heat-conducting channel structure 140 through the heat conduction structures 160, thereby more quickly dissipating the heat generated by the electronic component 600. It should be noted that the bottom sides 162 of the heat conduction structures 160 are adjacent to the liquid-cooled heat-conducting channel structure 140 (but not directly connected to the liquid-cooled heat-conducting channel structure 140), so that the present disclosure is capable of preventing the coolant from leaking from the liquid-cooled heat-conducting channel structure 140 while maintaining the heat dissipation efficiency (without affecting the heat conduction efficiency).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A composite circuit board structure having a component bonding area and a circuit layout area, comprising:
a glass substrate having an upper surface and a lower surface;
at least one conductive circuit disposed on the upper surface of the glass substrate and continuously distributed within the component bonding area and the circuit layout area;
a bottom substrate disposed on the lower surface of the glass substrate to contact the lower surface of the glass substrate;
a liquid-cooled heat-conducting channel structure disposed inside the glass substrate or the bottom substrate, wherein the liquid-cooled heat-conducting channel structure is disposed within the circuit layout area and the component bonding area; and
a plurality of heat conduction structures disposed inside the glass substrate located within the component bonding area;
wherein the heat conduction structures extend from the upper surface of the glass substrate to the lower surface of the glass substrate, and each of the heat conduction structures is adjacent to and separated from the liquid-cooled heat-conducting channel structure; and
wherein the liquid-cooled heat-conducting channel structure is configured to allow a coolant to flow therein.

2. The composite circuit board structure according to claim 1, wherein the liquid-cooled heat-conducting channel structure is disposed on the lower surface of the glass substrate, and the bottom substrate is connected to the lower surface of the glass substrate and connected to the liquid-cooled heat-conducting channel structure.

3. The composite circuit board structure according to claim 1,
wherein the liquid-cooled heat-conducting channel structure is disposed on an upper surface of the bottom substrate, and the lower surface of the glass substrate is connected to the upper surface of the bottom substrate and connected to the liquid-cooled heat-conducting channel structure; and
wherein a bottom side of each of the heat conduction structures extends into the bottom substrate and is separated from the liquid-cooled heat-conducting channel structure.

4. The composite circuit board structure according to claim 1, wherein a top side of each of the heat conduction structures is adjacent to the upper surface of the glass substrate, a bottom side of each of the heat conduction structures is located directly above the liquid-cooled heat-conducting channel structure, and a shortest distance between the bottom side of the heat conduction structure and the liquid-cooled heat-conducting channel structure is less than 5 μm.

5. The composite circuit board structure according to claim 1,
wherein the liquid-cooled heat-conducting channel structure includes a plurality of curved portions connected with each other, and the glass substrate is divided by the liquid-cooled heat-conducting channel structure to form a plurality of finger-shaped protrusions that are separated from each other;
wherein each of the heat conduction structures is disposed within a corresponding one of the finger-shaped protrusions of the glass substrate, each of the heat conduction structures has at least two sides facing the liquid-cooled heat-conducting channel structure, a top side of each of the heat conduction structures adjacent to the upper surface of the glass substrate, and a bottom side of each of the heat conduction structures adjacent to the lower surface of the glass substrate; and
wherein a shortest distance between the heat conduction structure and the liquid-cooled heat-conducting channel structure is less than 5 μm.

6. The composite circuit board structure according to claim 1,
wherein the liquid-cooled heat-conducting channel structure and the heat conduction structures are disposed on the same glass substrate;
wherein the liquid-cooled heat-conducting channel structure and the heat conduction structures are arranged side by side in a horizontal direction or a vertical direction, so that heat absorbed by each of the heat conduction structures is transferred to the liquid-cooled heat-conducting channel structure in the horizontal direction or the vertical direction;
wherein the liquid-cooled heat-conducting channel structure and the heat conduction structures are not disposed inside the bottom substrate; and
wherein the glass substrate and the bottom substrate are made of identical or different materials.

7. The composite circuit board structure according to claim 1,
wherein a portion of each of the heat conduction structures and the liquid-cooled heat-conducting channel structure are disposed inside the same bottom substrate; and
wherein the liquid-cooled heat-conducting channel structure is not disposed on the glass substrate.

8. A composite circuit board structure, comprising:
a glass substrate having an upper surface and a lower surface;
at least one conductive circuit disposed on the upper surface of the glass substrate;
a bottom substrate disposed on the lower surface of the glass substrate to contact the lower surface of the glass substrate;
a liquid-cooled heat-conducting channel structure passing through the glass substrate to contact an upper surface of the bottom substrate; and
a plurality of heat conduction structures disposed on the glass substrate and separated from the liquid-cooled heat-conducting channel structure;
wherein the liquid-cooled heat-conducting channel structure and the heat conduction structures are disposed inside the same glass substrate and arranged side by side horizontally or vertically; and
wherein the liquid-cooled heat-conducting channel structure and the heat conduction structures are not disposed inside the bottom substrate.

9. The composite circuit board structure according to claim 8,
wherein each of the heat conduction structures is configured to absorb heat;
wherein, when the liquid-cooled heat-conducting channel structure and the heat conduction structures are arranged side by side in a horizontal direction, the heat absorbed by each of the heat conduction structures is conducted horizontally to the liquid-cooled heat-conducting channel structure; and
wherein, when the liquid-cooled heat-conducting channel structure and the heat conduction structures are arranged side by side in a vertical direction, the heat absorbed by each of the heat conduction structures is conducted vertically to the liquid-cooled heat-conducting channel structure.

10. A composite circuit board structure, comprising:
a glass substrate having an upper surface and a lower surface;
at least one conductive circuit disposed on the upper surface of the glass substrate;
a bottom substrate disposed on the lower surface of the glass substrate to contact the lower surface of the glass substrate;
a liquid-cooled heat-conducting channel structure passing through the bottom substrate to contact the lower surface of the glass substrate; and
a plurality of heat conduction structures disposed inside both the glass substrate and the bottom substrate and separated from the liquid-cooled heat-conducting channel structure;
wherein the liquid-cooled heat-conducting channel structure and the heat conduction structures are arranged side by side in a horizontal direction; and
wherein the liquid-cooled heat-conducting channel structure is not disposed inside the glass substrate.
